(19) United States
(12) Patent Application Publication
(10) Pub. No.: US 2025/0022517 A1
(43) Pub. Date: Jan. 16, 2025

(54) MEMORY DEVICE AND OPERATING METHOD OF THE MEMORY DEVICE

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 18/390,456

(22) Filed: Dec. 20, 2023

(30) Foreign Application Priority Data
Jul. 14, 2023 (KR) 10-2023-0091784

(51) Int. Cl. G11C 16/26; G11C 16/08; G11C 16/34

(52) U.S. Cl. CPC G11C 16/26; G11C 16/08; G11C 16/3404

(57) ABSTRACT

A memory device and a method of operating the memory device include setting a read voltage to be applied to a selected word line among word lines connected to a memory block and setting a first pass voltage to be applied to an adjacent word line adjacent to the selected word line among the word lines. The method also includes applying the first pass voltage to the adjacent word line and applying the read voltage to the selected word line. The first pass voltage is set higher than a reference pass voltage when the read voltage is lower than a reference voltage. The first pass voltage is set lower than the reference pass voltage when the read voltage is higher than the reference voltage.

### CROSS-REFERENCE TO RELATED APPLICATION

The present application claims priority under 35 U.S.C. § 119 (a) to Korean patent application number 10-2023-0091784 filed on Jul. 14, 2023, in the Korean Intellectual Property Office, the entire disclosure of which is incorporated by reference herein.

### BACKGROUND

### 1. Technical Field

The present disclosure generally relates to a memory device and an operating method of the memory device, and more particularly, to a memory device configured to perform an erase operation and an operating method of the memory device.

### 2. Related Art

A memory device may include a memory cell array in which data is stored, a peripheral circuit configured to perform a program, read, or erase operation, and a control circuit configured to control the peripheral circuit.

The memory cell array may include a plurality of memory blocks, and each of the plurality of memory blocks may include a plurality of memory cells. A memory device having a three-dimensional structure may include memory cells stacked on a substrate. For example, the memory device having the three-dimensional structure may include plugs perpendicular to the substrate. The plugs may include select transistors connected between bit lines and a source line and memory cells connected between the select transistors. The memory cells and the select transistors between the bit lines and the source line may constitute strings.

The memory cells may have a program state or an erase state according to a threshold voltage. For example, memory cells having a threshold voltage higher than a reference voltage may have the program state, and memory cells having a threshold voltage lower than the reference voltage may have the erase state.

In a multi-level cell method in which two-or-more-bit data is stored in one memory cell, memory cells may be programmed to a plurality of program states. Therefore, a plurality of read voltages may be used to read memory cells corresponding to the plurality of program states in a read operation. For example, in the read operation, a read voltage may be applied to a selected word line, and a pass voltage may be applied to unselected word lines. The read voltage may be a voltage for determining a program state of selected memory cells, and the pass voltage may be a voltage for turning on unselected memory cells. The reliability of the read operation may be influenced by interference occurring from a voltage difference between the read voltage and the pass voltage, and therefore, it may be necessary to optimize the read voltage and the pass voltage.

### SUMMARY

Some embodiments are directed to a memory device and an operating method of the memory device, which may improve the reliability of a read operation of memory cells.

In accordance with an embodiment of the present disclosure, a method of operating a memory device includes: setting a read voltage to be applied to a selected word line among word lines connected to a memory block; setting a first pass voltage to be applied to an adjacent word line adjacent to the selected word line among the word lines; applying the first pass voltage to the adjacent word line; and applying the read voltage to the selected word line, wherein the first pass voltage is set higher than a reference pass voltage when the read voltage is lower than a reference voltage, and the first pass voltage is set lower than the reference pass voltage when the read voltage is higher than the reference voltage.

In accordance with another embodiment of the present disclosure, a method of operating a memory device includes: applying a read voltage to a selected word line; and applying a first pass voltage to adjacent word lines adjacent to the selected word line, wherein the first pass voltage becomes low when the read voltage becomes high.

In accordance with an embodiment of the present disclosure is a memory device including: a control circuit configured to select main voltage codes in response to a read command, generate offset codes according to the main voltage codes, and output operation codes including the main voltage codes and the offset codes; and a voltage generator configured to output read voltages and pass voltages in response to the operation codes, wherein the voltage generator is configured to output the pass voltages to which an offset voltage is applied according to the offset codes.

In accordance with another embodiment of the present disclosure is a memory device including: a control circuit configured to output operation codes in response to a read command; and a voltage generator configured to generate main voltage signals and trimming signals in response to the operation codes, and output read voltages and pass voltages in response to the main voltage signals and the trimming signals, wherein the voltage generator is configured to output the read voltages in response to the main voltage signals, and apply an offset voltage to the pass voltages in response to the trimming signals.

In accordance with still another embodiment of the present disclosure is a method of operating a memory device, the method including: setting main read voltages; resetting read voltages by decreasing levels of the main read voltages when the main read voltages are selected in an order from a low voltage to a high voltage in a read operation; and sequentially applying the read voltages to a selected word line.

In accordance with still another embodiment of the present disclosure is a method of operating a memory device, the method including: setting main read voltages; resetting read voltages by increasing a level of the main read voltage when the main read voltages are selected in an order from a high voltage to a low voltage in a read operation; and sequentially applying the read voltages to a selected word line.

In accordance with still another embodiment of the present disclosure is a method of operating a memory device, the method including: setting verify voltages; setting read voltages corresponding to the verify voltages; and reading memory cells connected to a selected word line by sequentially applying the read voltages to the selected word line, wherein voltage differences between the read voltages and the verify voltages become larger as levels of the verify voltages becomes higher.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device.

FIG. 2 is a circuit diagram illustrating a memory block.

FIG. 3 is a diagram illustrating a threshold voltage distribution of memory cells.

FIG. 4 is a diagram illustrating a control circuit in accordance with an embodiment of the present disclosure.

FIG. 5 is a diagram illustrating a voltage generator in accordance with an embodiment of the present disclosure.

FIG. 6 is a diagram illustrating voltages applied to a memory block in a read operation.

FIG. 7 is a diagram illustrating a read operation in accordance with a first embodiment of the present disclosure.

FIG. 8 is a diagram illustrating voltages corresponding to a threshold voltage distribution in the read operation in accordance with a first embodiment of the present disclosure.

FIGS. 9A, 9B, and 9C are diagrams illustrating voltages applied to a selected word line and unselected word lines in the read operation in accordance with a first embodiment of the present disclosure.

FIGS. 10 and 11 are diagrams illustrating a read operation in accordance with a second embodiment of the present disclosure.

FIGS. 12 and 13 are diagrams illustrating a read operation in accordance with a third embodiment of the present disclosure.

FIG. 14 is a diagram illustrating a read operation in accordance with a fourth embodiment of the present disclosure.

FIG. 15 is a diagram illustrating a memory card system to which the memory device of the present disclosure is applied.

FIG. 16 is a diagram illustrating a Solid-State Drive (SSD) system to which the memory device of the present disclosure is applied.

### DETAILED DESCRIPTION

The specific structural and functional descriptions disclosed herein are merely illustrative for the purpose of describing embodiments according to the concept of the present disclosure. Additional embodiments according to the concept of the present disclosure can be implemented in various forms. Thus, the present disclosure should not be construed as limited to the embodiments set forth herein.

Hereinafter, it will be understood that, although the terms “first,” “second,” etc. may be used herein to describe various elements, these elements should not be limited by these terms. These terms are only used to distinguish one element from another element and not to imply a number or order of elements.

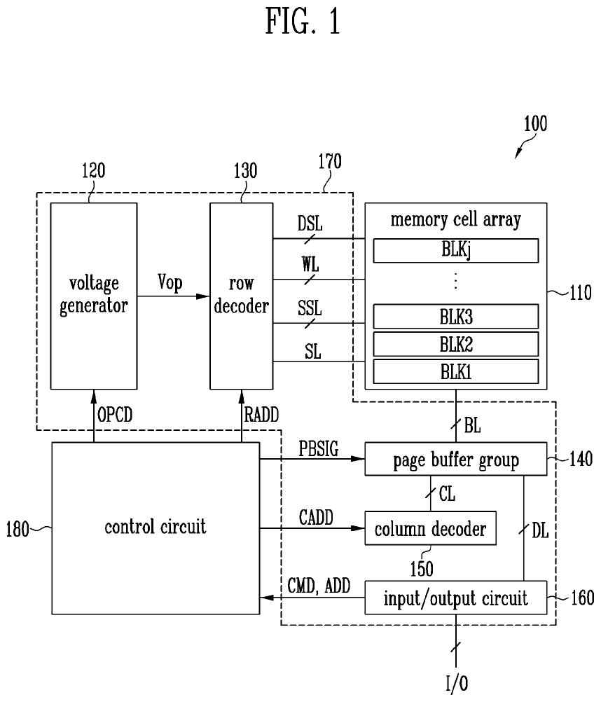

FIG. 1 is a diagram illustrating a memory device.

Referring to FIG. 1, the memory device 100 may include a memory cell array 110, a peripheral circuit 170, and a control circuit 180.

The memory cell array 110 may include first to jth memory blocks BLK1 to BLKj. Each of the first to jth memory blocks BLK1 to BLKj may include memory cells capable of storing data. Drain select lines DSL, word lines WL, source select lines SSL, and a source line SL may be connected to each of the first to jth memory blocks BLK1 to BLKj, and bit lines BL may be commonly connected to the first to jth memory blocks BLK1 to BLKj. The first to jth memory blocks BLK1 to BLKj may be formed in a three-dimensional structure. The memory blocks having the three-dimensional structure may include memory cells stacked on a substrate.

The memory cells may store one-bit or two-or-more-bit data according to a program method. For example, a method in which one-bit data is stored in one memory cell is referred to as a single-level cell method, and a method in which two-bit data is stored in one memory cell is referred to as a multi-level cell method. A method in which three-bit data is stored in one memory cell is referred to as a triple-level cell method, and a method in which four-bit data is stored in one memory cell is referred to as a quad-level cell method. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to operation codes OPCD. For example, the voltage generator 120 is configured to generate program voltages, turn-on voltages, turn-off voltages, negative voltages, a precharge voltage, verify voltages, read voltages, pass voltages, and erase voltages in response to the operation codes OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation, and may be used to increase a threshold voltage of memory cells connected to the selected word line. The turn-on voltages may be applied to the drain select lines DSL or the source select lines SSL, and be used to turn on drain select transistors or source select transistors. The turn-off voltages may be applied to the drain select lines DSL or the source select lines SSL, and be used to turn off the drain select transistors or the source select transistors. For example, the turn-off voltage may be set to 0V. The precharge voltage may be applied to the source line SL, and be used to increase a channel voltage of unselected strings in a soft program operation or a normal program operation. The negative voltages may be set to voltages lower than 0V. The verify voltages may be used in a verify operation for deciding whether a threshold voltage of selected memory cells has been increased or decreased to a target level. The verify voltages may be set to various levels according to the target level, and be applied to a selected word line. The read voltages may be applied to a selected word line in a read operation of selected memory cells. The pass voltages are voltages applied to unselected word lines in a program or read operation, and may be used to turn on memory cells connected to the unselected word lines. The erase voltages may be used in an erase operation for erasing memory cells included in a selected memory block, and be applied to the source line SL.

The voltage generator 120 may adjust levels of voltages applied to the drain select lines DSL, the word lines WL, the source select lines SSL, and the source line SL and times at which the voltages are output in response to the operation codes OPCD. The voltage generator 120 may discharge lines to which the operating voltages Vop are applied, and adjust times at which the lines are discharged. The voltage generator 120 may float selected lines. For example, the voltage generator 120 may generate operating voltages Vop including a read voltage and a pass voltage in response to the operation codes OPCD. Alternatively, the voltage generator 120 may generate an offset voltage according to the operation codes OPCD output from the control circuit 180, and generate operating voltages Vop to which the offset voltage is applied.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines, and may be connected to the first to jth memory blocks BLK1 to BLKj through the drain select lines DSL, the word lines WL, the source select lines SSL, and the source line SL.

The page buffer group 140 may include page buffers (not shown) connected to each of the first to jth memory blocks BLK1 to BLKj through the bit lines BL. In a program operation, program data transferred from the input/output circuit 160 may be stored in the page buffer group 140. The page buffer group 140 may apply a program allow voltage or a program inhibit voltage to the bit lines BL according to the program data in response to page buffer control signals PBSIG. In a verify operation, the page buffer group 140 may sense a current or a voltage of the bit lines BL, which varies according to threshold voltages of selected memory cells, and store sensed data.

The column decoder 150 may be configured to transmit data between the page buffer group 140 and the input/output circuit 160 in response to a column address CADD. For example, the column decoder 150 may be connected to the page buffer group 140 through column lines CL, and transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output an operation codes OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block and output read data. When the command CMD input to the control circuit 180 is a command corresponding to an erase operation, the control circuit 180 may control the peripheral circuit 170 to perform the erase operation of the selected memory block.

In the read operation in accordance with this embodiment, the control circuit 180 may output set operation codes OPCD or output operation codes OPCD obtained by applying an offset code to a main voltage code in response to a command corresponding to the read operation.

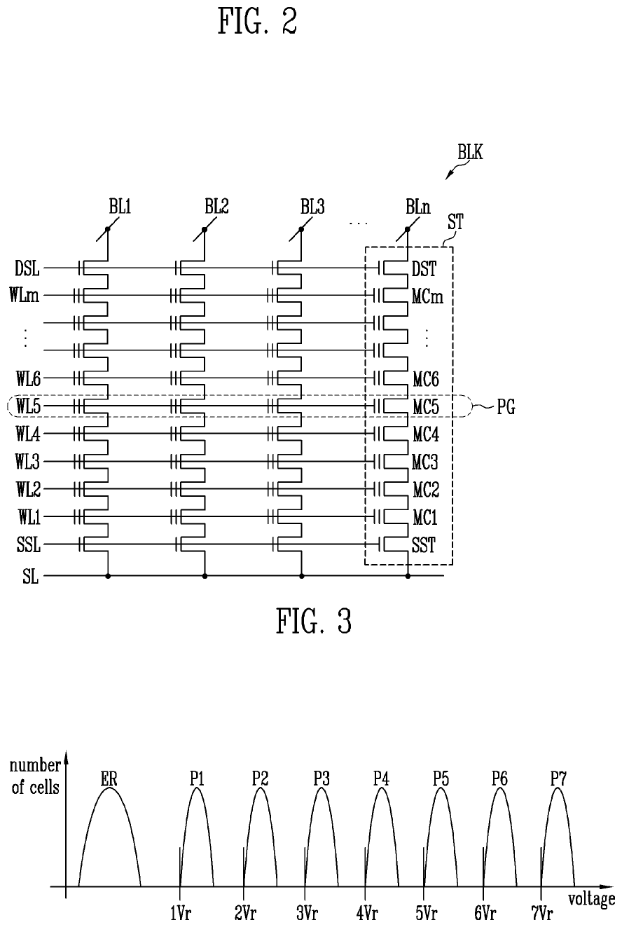

FIG. 2 is a circuit diagram illustrating a memory block.

Referring to FIG. 2, the memory block BLK may be any one of the first to jth memory blocks BLK1 to BLKj shown in FIG. 1. The memory block BLK may include strings ST connected between first to nth bit lines BL1 to BLn and a source line SL. For example, the strings ST may be commonly connected to the source line SL, and be respectively connected to the first to nth bit lines BL1 to BLn. A structure of a string ST connected between the nth bit line BLn and the source line SL is described as an example as follows.

The string ST may include a source select transistor SST, memory cells MC1 to MCm, and a drain select transistor DST, which are connected in series between the source line SL and the nth bit line BLn. The string ST shown in FIG. 2 is an example for describing a configuration of the memory block, and therefore, the number of the source select transistor SST, the memory cells MC1 to MCm, and the drain select transistor DST, which are included in the string ST, may be changed according to a memory device. In addition, dummy cells may be further included at a portion between the source select transistor SST, the memory cells MC1 to MCm, and the drain select transistor DST. The dummy cells are cells used to prevent electrical degradation of the string ST or improve an electrical characteristic of the string ST. The dummy cells do not store normal data but may store dummy data. The normal data may be stored in the memory cells MC1 to MCm.

The source select transistor SST may be configured to electrically connect the source line SL and first memory cells MC1 to each other or to electrically interrupt the connection between the source line SL and the first memory cells MC1. Gates of source select transistors SST included in different strings ST may be connected to a source select line SSL. The memory cells MC1 to MCm may be configured to store normal data. Gates of memory cells MC1 to MCm included in different strings ST may be respectively connected to word lines WL1 to WLm. A group of memory cells connected to the same word line may constitute a page PG, and a program operation or a read operation may be performed in units of pages. Drain select transistors DST included in different strings ST may be configured to electrically connect the bit lines BL1 to BLn and mth memory cells MCm or to electrically interrupt the connection between the bit lines BL1 to BLn and the mth memory cells MCm. Gates of drain select transistors DST included in different strings ST may be connected to a drain select line DSL.

FIG. 3 is a diagram illustrating a threshold voltage distribution of memory cells.

Referring to FIG. 3, memory cells may be divided into various states according to a threshold voltage, and the threshold voltage may have different levels according to data stored in the memory cells. For example, the memory cells may store one-bit or two-or-more-bit data according to a program method. A method in which one-bit data is stored in one memory cell is referred to as a single-level cell method, and a method in which two-bit data is stored in one memory cell is referred to as a multi-level cell method. A method in which three-bit data is stored in one memory cell is referred to as a triple-level cell method, and a method in which four-bit data is stored in one memory cell is referred to as a quad-level cell method. In addition, five-or-more-bit data may be stored in one memory cell. In FIG. 3, a threshold voltage distribution of the triple-level cell method is illustrated as an example. However, this embodiment is not limited to the triple-level cell method.

In the triple-level cell method, memory cells may be programmed to an erase state ER or any one of first to seventh program states P1 to P7 according to a threshold voltage. A program operation refers to an operation of increasing a threshold voltage of memory cells in the erase state ER to a threshold voltage corresponding to any one of the first to seventh program states P1 to P7. A read operation refers to an operation of deciding whether memory cells are in the erase state ER or any one of the first to seventh program states P1 to P7 and outputting data corresponding to the corresponding state. An erase operation refers to an operation of decreasing a threshold voltage of memory cells corresponding to the first to seventh program states P1 to P7 to a threshold voltage corresponding to the erase state ER. The read operation may use first to seventh read voltages 1Vr to 7Vr to decide a threshold voltage distribution of memory cells in different states. For example, the first read voltage 1Vr may be a voltage for distinguishing memory cells in the erase state ER from memory cells in a state higher than the erase state ER, and the second read voltage 2Vr may be a voltage for distinguishing memory cells in the first program state P1 or a state lower than the first program state P1 from memory cells in a state higher than the first program state P1. Therefore, the seventh read voltage 7Vr may be a voltage for distinguishing memory cells in the seventh program state P7 from memory cells in a state lower than the seventh program state P7.

The read operation may be performed using each of the first to seventh read voltages 1Vr to 7Vr, and data may be output, which correspond to memory cells divided through the operation performed using each of the first to seventh read operations 1Vr to 7Vr.

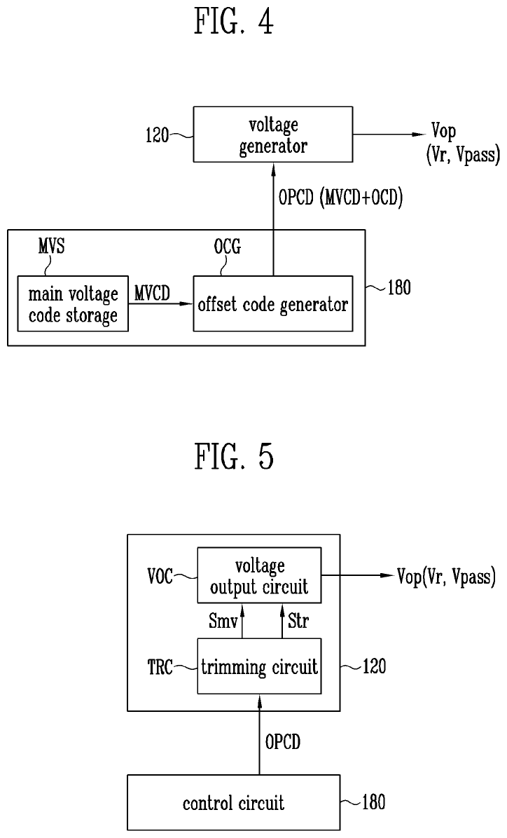

FIG. 4 is a diagram illustrating a control circuit in accordance with an embodiment of the present disclosure. FIG. 5 is a diagram illustrating a voltage generator in accordance with an embodiment of the present disclosure.

The memory device in accordance with this embodiment may include a control circuit 180 and a voltage generator 120, which are shown in FIG. 4, or include a control circuit 180 and a voltage generator 120, which are shown in FIG. 5.

Referring to FIG. 4, the control circuit 180 may include a main voltage code storage MVS and an offset code generator OCG.

The main voltage code storage MVS may store main voltage codes MVCD for generating main read voltages and a main pass voltage. For example, the main voltage codes MVCD may include main read voltage codes respectively corresponding to read voltages maintained at constant levels and a main pass voltage code corresponding to a pass voltage maintained at a constant level. A first main read voltage is described as an example. The main voltage codes MVCD may include a first main read voltage code for generating the first main read voltage and a main pass voltage code for generating a main pass voltage. The main pass voltage may be a voltage having a constant level regardless of the first main read voltage. That is, the main pass voltage code among the main voltage codes MVCD may be a code corresponding to a fixed level to turn on unselected memory cells regardless of the main read voltage. The main voltage code storage MVS may store a main voltage code table including the main read voltage codes and the main pass voltage code, and include a volatile memory or a nonvolatile memory.

The offset code generator OCG may be configured to output operation codes OPCD obtained by adding offset codes OCD to the main voltage codes MVCD. For example, the offset code generator OCG may add the offset codes OCD to the main read voltage codes or the main pass voltage code, which are included in the main voltage codes MVCD, thereby outputting the operation codes including the main voltage codes MVCD and the offset codes OCD.

The voltage generator 120 may be configured to output operating voltages including a read voltage Vr and a pass voltage Vpass in response to the main voltage codes MVCD and the offset codes OCD, which are included in the operation codes OPCD. For example, the voltage generator 120 may generate a main read voltage or a main pass voltage in response to the main voltage codes MVCD, and may increase or decrease the main read voltage or the main pass voltage by an offset voltage in response to the offset codes OCD.

Referring to FIG. 5, the control circuit 180 may be configured to output general operation codes OPCD, and the voltage generator 120 may be configured to output operating voltages Vop including a read voltage Vr and a pass voltage Vpass to which an offset voltage is applied in response to the operation codes OPCD. For example, the voltage generator 120 may include a trimming circuit TRC and a voltage output circuit VOC.

The trimming circuit TRC may be configured to output main voltage signals Smv and trimming signals Str in response to the operation codes OPCD. The main voltage signals Smv may be signals output in response to a read voltage code or a pass voltage code, which is included in the operation codes OPCD. The trimming signals Str may be signals for minutely adjusting a read voltage or a pass voltage.

The voltage output circuit VOC may be configured to output operating voltages Vop including a read voltage Vr or a pass voltage Vpass in response to the main voltage signals Smv and the trimming signals Str.

In addition to the control circuit 180 and the voltage generator 120, which are shown in FIG. 4 or 5, a control circuit 180 or a voltage generator 120 may be used, which is configured to adjust a level of a pass voltage according to a read voltage or to adjust a level of a read voltage according to a pass voltage.

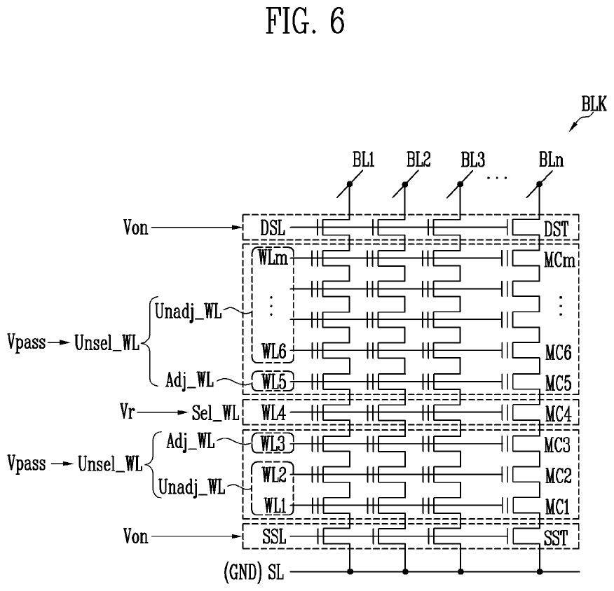

FIG. 6 is a diagram illustrating voltages applied to a memory block in a read operation.

Referring to FIG. 6, in the read operation, it is assumed that the fourth word line WL4 among the first to mth word lines WL1 to WLm connected to the memory block BLK is a selected word line Sel_WL. When the fourth word line WL4 is the selected word line Sel_WL, the other word lines, i.e., the first to third word lines WL1 to WL3 and the fifth to mth word lines WL5 to WLm, which are connected to the memory block BLK, may become unselected word lines Unsel_WL. The third and fifth word lines WL3 and WL5 adjacent to the selected word line Sel_WL among the unselected word lines Unsel_WL may become adjacent word lines Adj_WL, and the other unselected word lines WL1, WL2, and WL6 to WLm except the adjacent word lines Adj_WL among the unselected word lines Unsel_WL may become non-adjacent word lines Unadj_WL. In the drawing, the adjacent word lines Adj_WL are illustrated as two word lines respectively located at an upside and a downside of the selected word line Sel_WL. However, at least two word lines located at each of the upside and the downside may be included in the adjacent word lines Adj_WL. The non-adjacent word lines Unadj_WL may include the other word lines except the adjacent word lines Adj_WL and the selected word line Sel_WL.

A read voltage Vr may be applied to the selected word line Sel_WL, and a pass voltage may be applied to the unselected word lines Unsel_WL. In this embodiment, when the read voltage Vr is changed, the pass voltage Vpass applied to the adjacent word lines Adj_WL and the pass voltage applied to the non-adjacent word lines Unadj_WL may be adjusted differently from each other according to the changed read voltage. Alternatively, the pass voltage applied to the unselected word lines Unsel_WL may be constantly maintained, and the read voltage applied to the selected word line Sel_WL may be adjusted. The read voltage may be changed with respect to a predetermined read voltage or be changed with respect to a verify voltage used in a verify operation of a program operation.

In the read operation, a ground terminal GND may be connected to the source line SL, and a turn-on voltage Von may be applied to the drain and source select lines DSL and SSL.

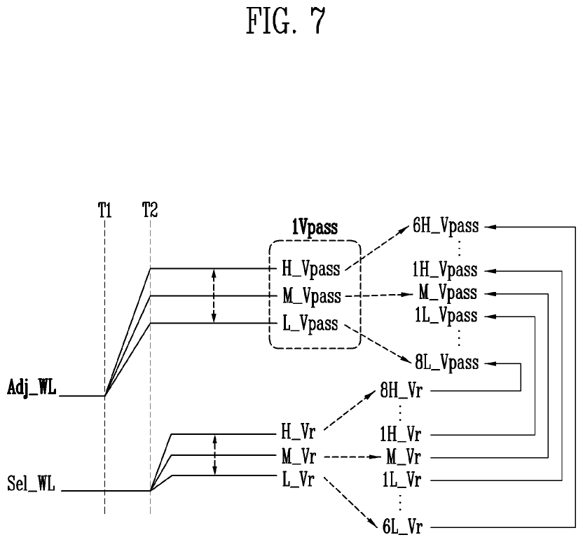

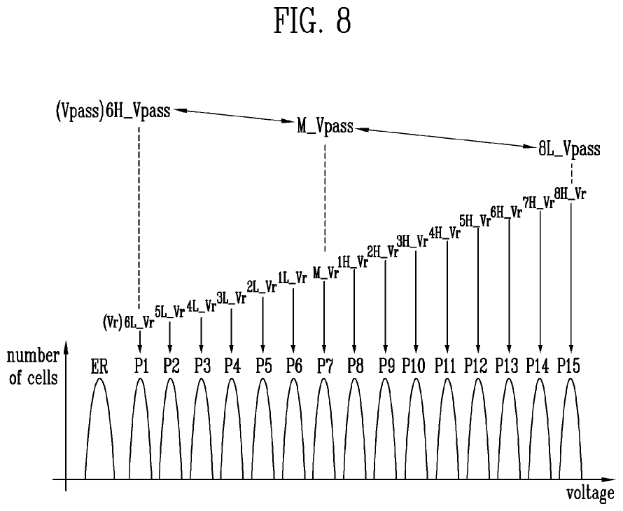

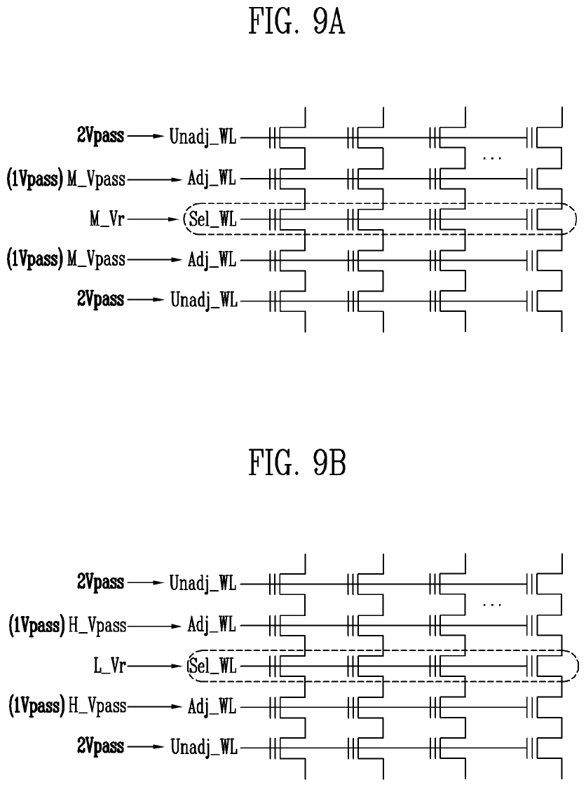

FIG. 7 is a diagram illustrating a read operation in accordance with a first embodiment of the present disclosure. FIG. 8 is a diagram illustrating voltages corresponding to a threshold voltage distribution in the read operation in accordance with a first embodiment of the present disclosure. FIGS. 9A to 9C are diagrams illustrating voltages applied to a selected word line and unselected word lines in the read operation in accordance with a first embodiment of the present disclosure.

Referring to FIGS. 7 and 8, in the read operation, after a pass voltage is applied to unselected word lines Unsel_WL, a read voltage may be applied to a selected word line Sel_WL. For example, at a first time T1, the pass voltage may be applied to the unselected word lines Unsel_WL. A potential of the selected word line Sel_WL may be 0V. At a second time T2 at which a potential of the unselected word lines Unsel_WL is increased to a set pass voltage, the read voltage may be applied to the selected word line Sel_WL.

The read voltages applied to the selected word line Sel_WL may be changed according to a target threshold voltage. For example, a plurality of different read voltages may be used to decide a threshold voltage distribution of memory cells corresponding to a plurality of program states. Therefore, a read voltage lower than a middle read voltage M_Vr among the plurality of read voltages may become a low read voltage L_Vr, and a read voltage higher than the middle read voltage M_Vr may become a high read voltage H_Vr. That is, the middle read voltage M_Vr may be a reference voltage.

A read operation of a triple-level cell method is described as an example. In the triple-level cell method, memory cells may be programmed to an erase state ER or any one state among first to fifteenth program states P1 to P15. Therefore, 15 different read voltages 6L_Vr to 1L_Vr, M_Vr, and 1H_Vr to 8H_Vr may be used to divide memory cells corresponding to the erase state ER and the first to fifteenth program states P1 to P15.

When assuming that a middle read voltage M_Vr is a voltage for distinguishing the sixth and seventh program states P6 and P7 from each other, a read voltage lower than the middle read voltage M_Vr becomes a first low read voltage 1L_Vr. A read voltage lower than the first low read voltage 1L_Vr becomes a second low read voltage 2L_Vr. In this manner, first to sixth low read voltages 1L_Vr to 6L_Vr lower than the middle read voltage M_Vr may be set. The sixth low read voltage 6L_Vr may be a lowest voltage among the read voltages. A read voltage higher than the middle read voltage M_Vr becomes a first high read voltage 1H_Vr. A read voltage higher than the first high read voltage 1H_Vr becomes a second high read voltage 2H_Vr. In this manner, first to eighth high read voltages 1H_Vr to 8H_Vr higher than the middle read voltage M_Vr may be set. The eighth high read voltage 8H_Vr may be a highest voltage among the read voltages.

In this embodiment, a first pass voltage 1Vpass applied to adjacent word lines Adj_WL adjacent to the selected word line Sel_WL among the unselected word lines may be set according to the read voltage applied to the selected word line Sel_WL. The adjacent word lines Adj_WL may be unselected word lines Unsel_WL respectively adjacent to an upside and a downside of the selected word line Sel_WL as described with reference to FIG. 6. In the drawings, one unselected word line adjacent to the downside from the selected word line Sel_WL and one unselected word line adjacent to the upside from the selected word line Sel_WL are illustrated as the adjacent word lines Adj_WL. However, the number of adjacent word lines Adj_WL is not limited to that shown in the drawings. Second pass voltages may be applied to the other word lines except the selected word line Sel_WL and the adjacent word lines Adj_WL. The other unselected word lines may be the non-adjacent word lines Unadj_WL described with reference to FIG. 6. The second pass voltages applied to the non-adjacent word lines Unadj_WL may be set regardless of the first pass voltage 1Vpass.

The pass voltage applied to the adjacent word lines Adj_WL may be set higher as the read voltage becomes lower, and be set lower as the read voltage becomes lower. For example, when the read voltage applied to the selected word line Sel_WL is set to a high read voltage H_Vr, the first pass voltage 1Vpass applied to the adjacent word lines Adj_WL may be set to a low pass voltage L_Vpass. When the read voltage applied to the selected word line Sel_WL is set to a middle read voltage M_Vr, the first pass voltage 1Vpass applied to the adjacent word lines Adj_WL may be set to a middle pass voltage M_Vpass. When the read voltage applied to the selected word line Sel_WL is set to a low read voltage L_Vr, the first pass voltage 1Vpass applied to the adjacent word lines Adj_WL may be set to a high pass voltage H_Vpass. The high read voltage H_Vr is higher than the middle read voltage M_Vr, and the low read voltage L_Vr is lower than the middle read voltage M_Vr. The high pass voltage H_Vpass is higher than the middle pass voltage M_Vpass, and the low pass voltage L_Vpass is lower than the middle pass voltage M_Vpass. That is, when assuming that the middle read voltage M_Vr is a reference voltage, the middle pass voltage M_Vpass may become a reference pass voltage. Therefore, when the read voltage is higher than the reference voltage, the first pass voltage 1Vpass may be set to the low read voltage L_Vr lower than the reference pass voltage. When the read voltage is lower than the reference voltage, the first pass voltage 1Vpass may be set to the high read voltage H_Vr higher than the reference pass voltage. The second pass voltages applied to the non-adjacent word lines may be set equal to or different from the first pass voltage 1Vpass.

Referring to FIGS. 7 and 9A to 9C, when the read voltage applied to the selected word line Sel_WL becomes low, a potential of the adjacent word lines Adj_WL may become low due to coupling between the selected word line Sel_WL and the adjacent word lines Adj_WL. Therefore, in the first embodiment, the first pass voltage 1Vpass applied to the adjacent word lines Adj_WL may be set higher as the read voltage becomes lower, and be set lower as the read voltage becomes higher. The first pass voltage 1Vpass applied to the adjacent word lines Adj_WL may be set in inverse proportion to the read voltage applied to the selected word line Sel_WL. A variation of the first pass voltage 1Vpass applied to the adjacent word lines Adj_WL may be set in proportion to a variation of the read voltage applied to the selected word line Sel_WL.

That is, to compensate for a potential change of the adjacent word lines Adj_WL due to the coupling between the selected word line Sel_WL and the adjacent word lines Adj_WL, an offset voltage may be applied to an initial pass voltage set in the adjacent word lines Adj_WL. The second pass voltages 2Vpass applied to the non-adjacent word lines Unadj_WL may be set to one fixed voltage or be set to voltages having various levels.

When the read voltage to be applied to the selected word line Sel_WI is set to the middle read voltage M_Vr (see FIG. 9A), the first pass voltage 1Vpass to be applied to the adjacent word lines Adj_WL may be set to the middle pass voltage M_Vpass.

When the read voltage to be applied to the selected word line Sel_WI is set to the low read voltage L_Vr lower than the middle read voltage M_Vr (see FIG. 9B), the first pass voltage 1Vpass to be applied to the adjacent word lines Adj_WL may be set to the high pass voltage H_Vpass higher than the middle pass voltage M_Vpass.

When the read voltage to be applied to the selected word line Sel_WI is set to the high read voltage H_Vr higher than the middle read voltage M_Vr (see FIG. 9C), the first pass voltage 1Vpass to be applied to the adjacent word lines Adj_WL may be set to the low pass voltage L_Vpass higher than the middle pass voltage M_Vpass. In this manner, the first pass voltage 1Vpass to be applied to the adjacent word lines Adj_WL may be selected from the middle pass voltage M_Vpass, first to eighth low pass voltages 1L_Vpass to 8L_Vpass, and first to sixth high pass voltages 1H_Vpass to 6H_Vpass.

As described above, when the first pass voltage 1Vpass applied to the adjacent word lines Adj_WL is adjusted, a voltage difference due to the coupling between the selected word line Sel_WL and the adjacent word lines Adj_WL can be decreased. Accordingly, the reliability of an operation of sensing a voltage or current of bit lines, which varies according to a threshold voltage of selected memory cells in the read operation can be improved.

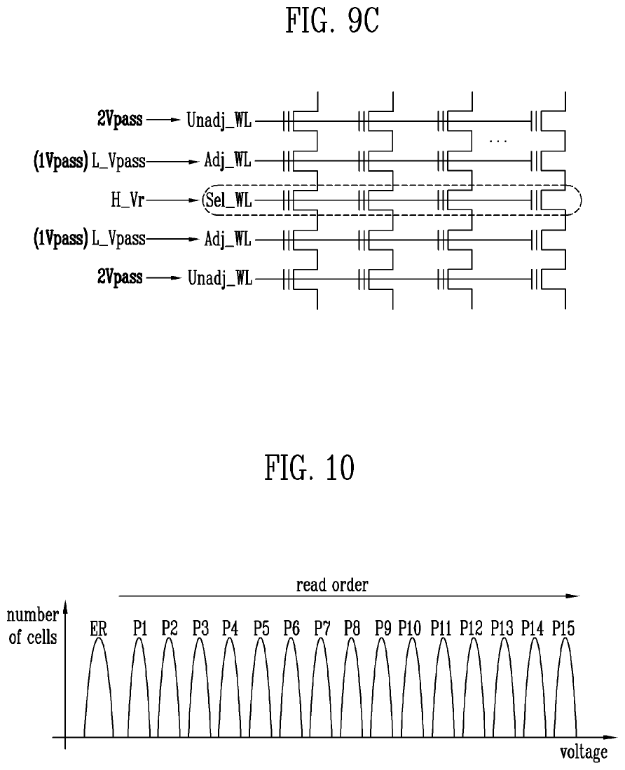

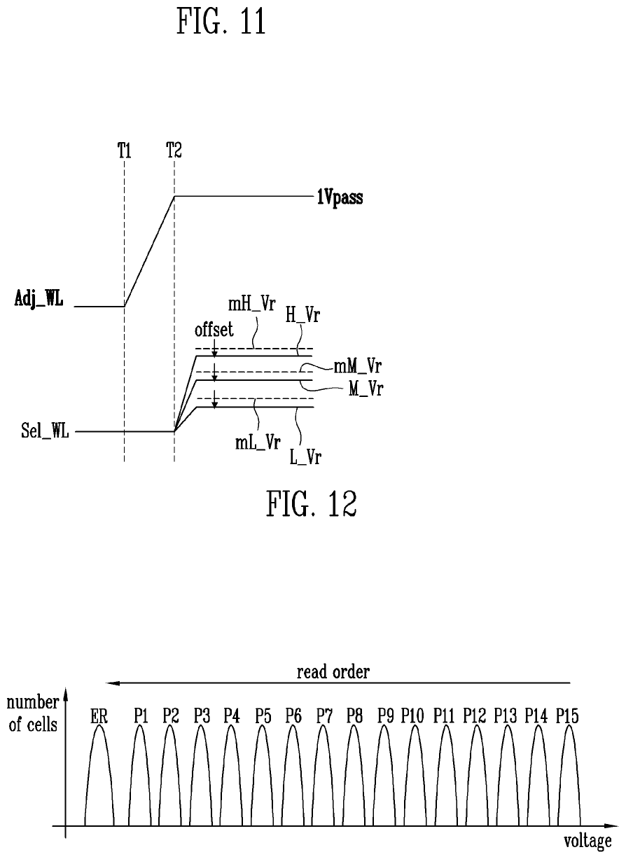

FIGS. 10 and 11 are diagrams illustrating a read operation in accordance with a second embodiment of the present disclosure.

Referring to FIGS. 10 and 11, read voltages may be adjusted according to a sequence of a read operation. The sequence of the read operation refers to a sequence in which the read voltages are selected. For example, in a read operation of a selected page, a plurality of read voltages may be sequentially selected to divide memory cells having an erase state ER or any one state among first to fifteenth program states P1 to P15. A low read voltage may be used in a read operation for dividing memory cells having a low threshold voltage distribution, and a high read voltage may be used in a read operation for dividing memory cells having a high threshold voltage distribution.

In the read operation in accordance with the second embodiment, the read operation may be performed using a method in which read voltages are sequentially selected in an order from a low read voltage to a high read voltage, and the read voltage may be reset to a voltage lower than a main read voltage. That is, a negative offset voltage may be applied to the read voltage. Because the read voltage is increased stepwise, the read voltage is reset lower than the main read voltage to reduce coupling caused by the increased read voltage. For example, a low read voltage L_Vr may be reset to a voltage which is lower than a main low read voltage mL_Vr and is higher than 0V. A middle read voltage M_Vr may be reset to a voltage which is lower than a main middle read voltage mM_Vr and is higher than the main low read voltage mL_Vr. A high read voltage H_Vr may be reset to a voltage which is lower than a main high read voltage mH_Vr and is higher than the main middle read voltage mM_Vr. In the second embodiment, a first pass voltage 1Vpass applied to adjacent word lines Adj_WL may be constantly maintained as a middle pass voltage M_Vpass regardless of the read voltage. Although not shown in the drawings, second pass voltages set separately from the first pass voltage 1Vpass may be applied to non-adjacent word lines.

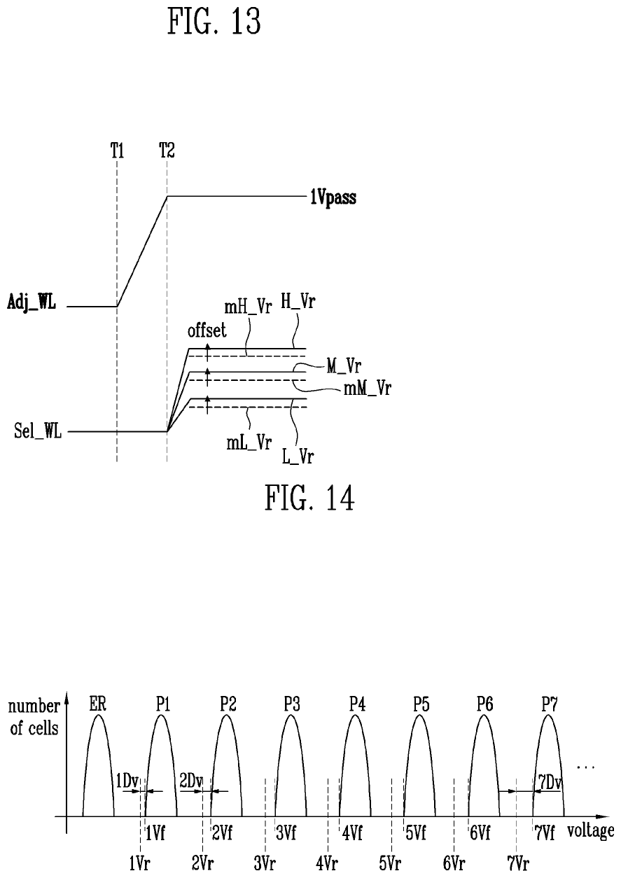

FIGS. 12 and 13 are diagrams illustrating a read operation in accordance with a third embodiment of the present disclosure.

Referring to FIGS. 12 and 13, in the read operation in accordance with the third embodiment, the read operation may be performed using a method in which read voltages are sequentially selected in an order from a high read voltage to a low read voltage, and the read voltage may be reset to a voltage higher than a main read voltage. That is, a positive offset voltage may be applied to the read voltage. Because the read voltage is decreased stepwise, the read voltage is reset higher than the main read voltage to reduce coupling caused by the decreased read voltage. For example, a low read voltage L_Vr may be reset to a voltage which is higher than a main low read voltage mL_Vr and is lower than a main middle voltage mM_Vr. A middle read voltage M_Vr may be reset to a voltage which is higher than the main middle voltage mM_Vr and is lower than a main high read voltage mH_Vr. A high read voltage H_Vr may be reset to a voltage higher than the main high read voltage mH_Vr. In the third embodiment, a first pass voltage 1Vpass applied to adjacent word lines Adj_WL may be constantly maintained as a middle pass voltage M_Vpass regardless of the read voltage. Although not shown in the drawings, second pass voltages set separately from the first pass voltage 1Vpass may be applied to non-adjacent word lines.

FIG. 14 is a diagram illustrating a read operation in accordance with a fourth embodiment of the present disclosure.

Referring to FIG. 14, read voltages may be changed according to verify voltages. The read voltages may be reset to have levels lower than a level of a verify voltage. A read voltage corresponding to a high verify voltage may be reset such that a voltage difference between the verify voltage and the read voltage increases, and a read voltage corresponding to a low verify voltage may be reset such that a voltage difference between the verify voltage and the read voltage decreases.

The verify voltage is a voltage used in a verify operation for checking whether a threshold voltage of memory cells has been increased to a target level in a program operation. A program operation of a triple-level cell method is described as an example. First to seventh verify voltages 1Vf to 7Vf may be used to verify memory cells corresponding to an erase state ER or any one state among first to seventh program states P1 to P7. The first verify voltage 1Vf is a voltage for detecting memory cells programmed to the first program state P1 or a state higher than the same, and the second verify voltage 2Vf is a voltage for detecting memory cells programmed to the second program state P2 or a state higher than the same. The seventh verify voltage 7Vf is a voltage for detecting memory cells programmed to the seventh program state P7.

In the read operation, a first read voltage 1Vr corresponding to the first verify voltage 1Vf may be reset to a voltage which is lower than the first verify voltage 1Vf and having a first voltage difference 1Dv from the first verify voltage 1Vf. A second read voltage 2Vr corresponding to the second verify voltage 2Vf higher than the first verify voltage 1Vf may be reset to a voltage which is lower than the second verify voltage 2Vf and has a second voltage difference 2Dv from the second verify voltage 2Vf. The second voltage difference 2Dv is greater than the first voltage difference 1Dv. A seventh read voltage 7Vr corresponding to the seventh verify voltage 7Vf highest among the first to seventh verify voltages 1Vf to 7Vf may be reset to a voltage which is lower than the seventh verify voltage 7Vf and has a seventh voltage difference 7Dv from the seventh verify voltage 7Vf. A pass voltage having a constant level regardless of the read voltage may be applied to the other unselected word lines except a selected word line to which a selected read voltage among first to seventh read voltages 1Vr to 7Vr is applied.

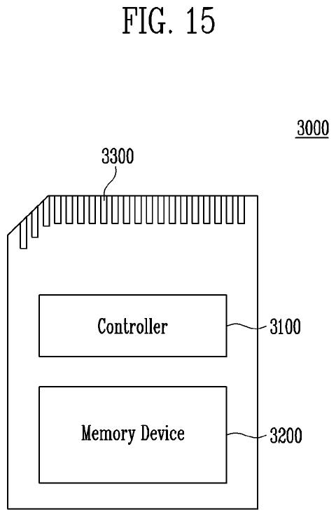

FIG. 15 is a diagram illustrating a memory card system to which the memory device of the present disclosure is applied.

Referring to FIG. 15, the memory card system 3000 includes a controller 3100, a memory device 3200, and a connector 3300.

The controller 3100 may be connected to the memory device 3200. The controller 3100 may access the memory device 3200. For example, the controller 3100 may control a program, read, or ease operation, or control a background operation of the memory device 3200. The controller 3100 may provide an interface between the memory device 3200 and a host. The controller 3100 may drive firmware for controlling the memory device 3200. For example, the controller 3100 may include components such as Random-Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. For example, the controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells, and be configured identically to the memory device 100 shown in FIG. 1. Therefore, the memory device 3200 may control a soft program operation for increasing a threshold voltage of dummy cells.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

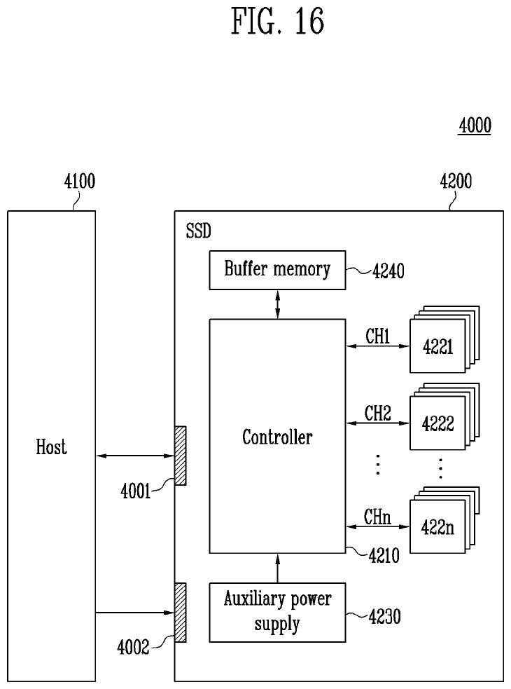

FIG. 16 is a diagram illustrating a Solid-State Drive (SSD) system to which the memory device of the present disclosure is applied.

Referring to FIG. 16, an SSD system 4000 includes a host 4100 and an SSD 4200. The SSD 4200 exchanges a signal with the host 4100 through a signal connector 4001, and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. Therefore, each of the plurality of memory devices 4221 to 422n may control a soft program operation for increasing a threshold voltage of dummy cells. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n, or temporarily store meta data (e.g., a mapping table) of the memory devices 4221 to 422n. The buffer memory 4240 may include volatile memory such as DRAM, SDRAM, DDR SDRAM, LPDDR SDRAM, and GRAM or nonvolatile memory such as FRAM, ReRAM, STT-MRAM, and PRAM.

In accordance with an embodiment of the present disclosure, the reliability of a read operation of the memory device in an erase operation can be improved.

While the present disclosure has been shown and described with reference to certain example embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described example embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the example embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A method of operating a memory device, the method comprising:
setting a read voltage to be applied to a selected word line among word lines connected to a memory block;
setting a first pass voltage to be applied to an adjacent word line adjacent to the selected word line among the word lines;
applying the first pass voltage to the adjacent word line; and
applying the read voltage to the selected word line,
wherein the first pass voltage is set higher than a reference pass voltage when the read voltage is lower than a reference voltage, and the first pass voltage is set lower than the reference pass voltage when the read voltage is higher than the reference voltage.

2. The method of claim 1, wherein the first pass voltage is set in inverse proportion to the read voltage.

3. The method of claim 1, wherein a variation of the first pass voltage is set in proportion to a variation of the read voltage.

4. The method of claim 1, wherein the read voltage is changed according to a threshold voltage distribution of memory cells.

5. The method of claim 1, further comprising setting a plurality of second pass voltages to be applied to the other non-adjacent word lines except the selected word line and the adjacent word line among the word lines, in the setting of the first pass voltage.

6. A method of operating a memory device, the method comprising:
applying a read voltage to a selected word line; and
applying a first pass voltage to adjacent word lines adjacent to the selected word line,
wherein the first pass voltage becomes low when the read voltage becomes high.

7. The method of claim 6, wherein the read voltage is applied to the selected word line after the first pass voltage is applied to the adjacent word lines.

8. The method of claim 6, wherein the first pass voltage becomes high when the read voltage becomes low.

9. The method of claim 6, wherein a variation of the first pass voltage increases when a variation of the read voltage increases.

10. The method of claim 6, wherein a variation of the first pass voltage decreases when a variation of the read voltage decreases.

11. The method of claim 6, wherein, when the first pass voltage is applied to the adjacent word lines, a second pass voltage unrelated to the first pass voltage is applied to the other non-adjacent word lines except the selected word line and the adjacent word lines.

12. A memory device comprising:
a control circuit configured to select main voltage codes in response to a read command, generate offset codes according to the main voltage codes, and output operation codes including the main voltage codes and the offset codes; and
a voltage generator configured to output read voltages and pass voltages in response to the operation codes,
wherein the voltage generator is configured to output the pass voltages to which an offset voltage is applied according to the offset codes.

13. The memory device of claim 12, wherein the control circuit includes:
a main voltage code storage configured to store the main voltage codes for generating main voltages; and
an offset code generator configured to generate the offset codes according to the main voltage codes selected by the main voltage code storage and output the operation codes.

14. The memory device of claim 12, wherein, when a level of the read voltage becomes high, the voltage generator is configured to output the pass voltage lower by the offset voltage than a main pass voltage in response to the operation codes.

15. The memory device of claim 12, wherein, when a level of the read voltage becomes low, the voltage generator is configured to output the pass voltage higher by the offset voltage than a main pass voltage in response to the operation codes.

16. A memory device comprising:
a control circuit configured to output operation codes in response to a read command; and
a voltage generator configured to generate main voltage signals and trimming signals in response to the operation codes, and output read voltages and pass voltages in response to the main voltage signals and the trimming signals,
wherein the voltage generator is configured to:
output the read voltages in response to the main voltage signals; and
apply an offset voltage to the pass voltages in response to the trimming signals.

17. The memory device of claim 16, wherein the voltage generator includes:
a trimming circuit configured to generate the main voltage signals and the trimming signals in response to the operation codes; and
a voltage output circuit configured to output the read voltages and the pass voltages in response to the main voltage signals and the trimming signals.

18. The memory device of claim 16, wherein, when a level of the read voltage becomes high, the voltage generator is configured to output the pass voltage lower by the offset voltage than a main pass voltage in response to the main voltage signals and the trimming signals.

19. The memory device of claim 16, wherein, when a level of the read voltage becomes low, the voltage generator is configured to output the pass voltage higher by the offset voltage than a main pass voltage in response to the main voltage signals and the trimming signals.
